(19) United States
(12) Patent Application Publication
(10) Pub. No.: US 2026/0101679 A1
(43) Pub. Date: Apr. 9, 2026

(54) NON-OXIDE DIELECTRIC SPACERS FOR RESISTIVE RANDOM-ACCESS MEMORY

(71) Applicant: Taiwan Semiconductor Manufacturing Company, Ltd., Hsinchu (TW)

(72) Inventors: Harry-Haklay Chuang, Zhubei City (TW); Yu-Wen Liao, New Taipei City (TW); Wen-Ting Chu, Kaohsiung City (TW); Hsia-Wei Chen, Taipei City (TW)

(21) Appl. No.: 19/010,563

(22) Filed: Jan. 6, 2025

Related U.S. Application Data
(60) Provisional application No. 63/704,113, filed on Oct. 7, 2024.

(51) Int. Cl. H10N 70/00; H10B 63/00; H10N 70/20

(52) U.S. Cl. CPC H10N 70/8265; H10B 63/00; H10N 70/063; H10N 70/24; H10N 70/841

(57) ABSTRACT

The problem of making the operating speed of a resistive random access memory (RRAM) cell independent of bottom electrode thickness is solved by incorporating a non-oxide dielectric layer that protects the bottom electrode from oxygen-induced damage during the formation of an inter-layer dielectric over the RRAM cell. The non-oxide dielectric layer may serve as a second spacer positioned over a first spacer that surrounds the top electrode. The first spacer may provide a lateral offset between the sidewall of the bottom electrode and the sidewall of the top electrode. The non-oxide dielectric layer is particularly beneficial in embodiments where the resistive switching structure is sensitive to oxygen encroachment originating from the bottom electrode.

### REFERENCE TO RELATED APPLICATION

This Application claims priority to U.S. Provisional Application No. 63/704,113, filed on Oct. 7, 2024, the contents of which are hereby incorporated by reference in their entirety.

### BACKGROUND

Many modern electronic devices contain electronic memory configured to store data. Electronic memory may be volatile or non-volatile. Volatile memory stores data while it is powered, while non-volatile memory is able to keep data when power is off. Resistive random-access memory (RRAM) is one promising candidate for next generation non-volatile memory due to its simple structure and compatibility with complementary metal-oxide semiconductor (CMOS) processes. An RRAM cell includes a resistive switching structure having a variable resistance. The resistive switching structure is generally placed between two electrodes disposed within a metal interconnect structure.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-2 illustrate cross-sectional views of integrated circuit devices in accordance with various embodiments. The devices include resistive random-access memory (RRAM) cells with bottom electrodes protected by non-oxide dielectric layers, as taught by the present disclosure.

FIGS. 3-4 cross-sectional view showing larger portions of the integrated circuit device of FIG. 2, in accordance with various embodiments.

FIG. 5 provides an enlarged view of a portion of the RRAM cell of FIG. 2, in accordance with an embodiment.

FIGS. 6-7 illustrate cross-sectional views of additional integrated circuit devices in accordance with other embodiments. These devices include resistive random-access memory (RRAM) cells with bottom electrodes protected by non-oxide dielectric layers, as taught by the present disclosure.

FIGS. 8-17 illustrate cross-sectional views of an integrated circuit device including undergoing manufacturing in accordance with an embodiment of the present disclosure.

FIGS. 18-23 illustrate cross-sectional views of an integrated circuit device at various stages of manufacture in accordance with another embodiment.

FIGS. 24-25 provide cross-sectional views illustrating a variation on the process of FIGS. 18-23, in accordance with another embodiment.

FIGS. 26-31 illustrate cross-sectional views of an integrated circuit device at various stages of manufacture in accordance with another embodiment.

FIG. 32 provides a flowchart illustrating a method of forming and protecting an RRAM cell in accordance with some embodiments.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Integrated circuits may include resistive random-access memory (RRAM) cells, which have a resistive switching structure disposed between a top electrode and a bottom electrode. Current pulses can be used to reversibly switch the resistive switching structure between a high-resistance state (HRS) and a low-resistance state (LRS). The distinction between the HRS and the LRS provides a basis for data encoding. A read operation can use a lower voltage than the programming voltages, allowing the RRAM cell's state to be detected without altering it.

Before an RRAM cell is used to store data, an initial conductive filament is typically formed across the resistive switching structure. The formation of the initial conductive filament makes subsequent programming operations easier. The initial conductive filament is formed by pulsing a forming voltage across the top and bottom electrodes.

In some types of RRAM cells, the resistive switching structure includes metal oxides and the conductive filament is formed by oxygen vacancies within the metal oxide structure. In these types of RRAM cells, forming voltage pulses may break metal oxide bonds and free oxygen ions. The freed oxygen ions migrate toward the top electrode, where some are absorbed. The migration of oxygen ions leaves behind oxygen vacancies. New oxygen vacancies form more easily adjacent to pre-existing oxygen vacancies, so the oxygen vacancies tend to align to form a conductive filament that extends continuously through the resistive switching structure.

After the initial conductive filament is formed, the RRAM cell can be switched between the HRS and the LRS using voltages lower than the forming voltage. In a reset operation, the oxygen ions are driven to return to approximately their original positions, rendering the conductive filament no longer operative. During a set operation the oxygen ions are once again driven toward and into the top electrode reestablishing the conductive filament.

The drive toward increasing integrated circuit device density has resulted in a long felt need to make RRAM cells smaller. One approach to achieving this involves providing them with a non-planar structure by forming the RRAM cell stack over a hole or recess in a dielectric layer. The bottom electrode, resistive switching structure, and top electrode of the resulting RRAM cell may each have central depressions over the hole or recess. This structure helps increase the electric field strength in the central area and better confines the area in which the conductive filament forms, allowing the edges of the RRAM cell to be closer to its center. Providing the sidewalls with a tapered profile enhances these benefits by reducing the electric field intensity at the edges of the cell.

The inventors have found that under some circumstances, such as when the RRAM cells are very small and have tapered sidewalls, exposure of the bottom electrode sidewalls to oxygen after RRAM cell formation can cause significant damage. This damage may occur by altering the shape of the edges of the bottom electrode or by incorporating oxygen into its composition, which adversely affect the RRAM cell's performance. In accordance with the present disclosure, this damage is prevented by forming a non-oxide dielectric layer over the sidewalls before any subsequent processing in an oxidizing environment, such as the processing that forms the inter-layer dielectric.

In some embodiments, the RRAM cell is formed by a process that includes forming an RRAM cell stack and performing two stages of etching. The RRAM cell stack includes a bottom electrode layer, an RRAM switching layer, a top electrode layer, and often a hard mask layer. Any of these layers may comprise multiple sub-layers. The first stage of etching patterns the top electrode layer to define the top electrode and stops either on the RRAM switching layer, within the RRAM switching layer, or on the bottom electrode layer. A sidewall spacer is then formed around the top electrode. The second stage of etching patterns the RRAM switching layer to define the RRAM switching structure, if that was not completed during the first etching process, and patterns the bottom electrode layer in alignment with the sidewall spacer to define the bottom electrode. The sidewall spacer prevents damage to the operative portion of the RRAM switching layer during patterning of the bottom electrode. Previously, an additional spacer was not thought to be necessary, and the inter-layer dielectric was formed directly over the resulting structure. In accordance with the present disclosure, however, the non-oxide dielectric layer is provided as a second spacer formed outside of the sidewall spacer.

During the RRAM cell patterning process, edges of the top electrode may become exposed. This is particularly true if the RRAM cell stack is formed over a hole or recess, causing the edges of the top electrode to slope upward and have a greater elevation than a central area of the top electrode. These exposed edges are vulnerable to oxidation when forming the inter-layer dielectric. In some embodiments, the non-oxide dielectric layer extends over the top electrode layer to protect these edges.

The inter-layer dielectric is generally a low-k dielectric layer or an extremely low-k dielectric layer. These types of layers may not adhere well to the non-oxide dielectric layer. Accordingly, in some embodiments, a silicon dioxide layer is formed over the non-oxide dielectric layer to serve as an interfacial layer between the non-oxide dielectric layer and the inter-layer dielectric.

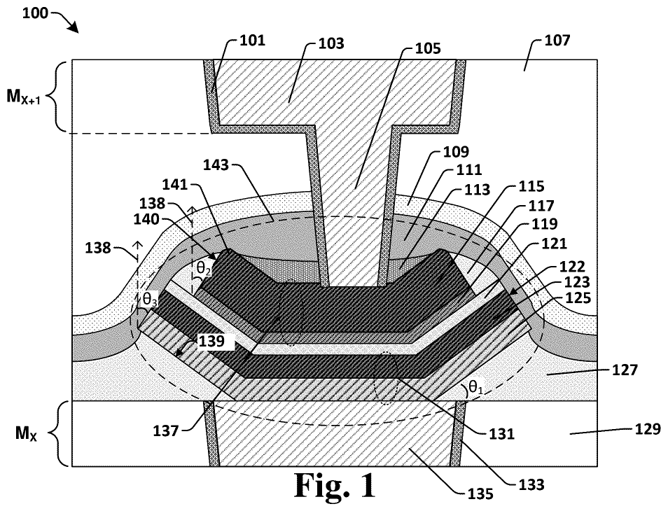

FIG. 1 illustrates a cross-sectional view of an integrated circuit device 100 that includes a resistive random-access memory (RRAM) cell 143 disposed between a first metallization layer M_{X} and a second metallization layer M_{X+1}, which are part of a metal interconnect structure over a semiconductor substrate (not shown). In accordance with the present disclosure, the RRAM cell 143 is surrounded by a non-oxide dielectric layer 111.

The RRAM cell 143 includes a bottom electrode 131, a resistive switching structure 121, and a top electrode 137. The bottom electrode 131 may include a barrier layer 125 and a bottom electrode metal layer 123. The barrier layer 125 provides a barrier between the bottom electrode metal layer 123 and a conductive trace 135 in the first metallization layer M_{X}. The top electrode 137 may include a capping structure 119 and a top electrode metal layer 115. The capping structure 119 facilitates the absorption of oxygen ions from the resistive switching structure 121.

The RRAM cell 143 is disposed over an opening defined by the sidewalls 139 of a dielectric layer 127. This configuration results in the bottom electrode 131, the resistive switching structure 121, and the top electrode 137 having central depressions. These layers taper upward from there central depressions to their outer edge at angles that are similar to an angle θ₁ which the sidewalls 139 form with a horizontal axis.

A sidewall spacer 117 positioned over the bottom electrode 131 surrounds the top electrode 137. The bottom electrode metal layer 123 has a sidewall 122 that is aligned with the sidewall spacer 117. The sidewall spacer 117 is entirely above the bottom electrode metal layer 123 in the sense that a bottom surface of the sidewall spacer 117 is vertically higher than an upper surface of the bottom electrode metal layer 123. The sidewall spacer 117 may extend only to an elevation at or below an upper surface of the top electrode 137 as a result of a forming process. A hard mask 113 may be disposed over the top electrode 137. A corner 141 of the top electrode 137 may protrude from between the sidewall spacer 117 and the hard mask 113.

The non-oxide dielectric layer 111 surrounds the sidewall spacer 117 and covers the sidewall 122 of the bottom electrode metal layer 123, providing a physical barrier between the bottom electrode 131 and an inter-layer dielectric 107. The non-oxide dielectric layer 111 is in direct contact with the sidewall 122 but may be separated from the inter-layer dielectric 107 by an interfacial layer 109. The non-oxide dielectric layer 111 extends over the top electrode 137 and the hard mask 113, covering the corner 141. The non-oxide dielectric layer 111 may be in direct contact with the corner 141.

A via 105 extends through the inter-layer dielectric 107, the interfacial layer 109, the non-oxide dielectric layer 111, and the hard mask 113 to form a connection between the top electrode 137 and a conductive trace 103 in the second metallization layer M_{X+1}. The via 105 and the conductive trace 103 may be separated from the inter-layer dielectric 107 by a diffusion barrier layer 101. Likewise, the conductive trace 135 may be separated from the lower inter-layer dielectric 129 by a diffusion barrier layer 133.

The top electrode 137 has a sidewall 140 that tapers at an angle θ₂ with respect to a vertical axis 138. In some embodiments, the angle θ₂ is in the range from about 10° to about 60°. In some embodiments, the angle θ₂ is in the range from about 15° to about 45°. Making the sidewall 140 sloped rather than vertical reduces the electric field intensity at the edge of the RRAM cell 143 but may make the corner 141 more prone to exposure during formation of the sidewall spacer 117 and during subsequent processing.

The sidewall 122 of the bottom electrode metal layer 123 tapers at an angle θ₃ with respect to a vertical axis. In some embodiments, the angle θ₃ is in the range from about 15° to about 75°. In some embodiments, the angle θ₃ is in the range from about 30° to about 60°. Making the sidewall 122 sloped rather than vertical reduces the electric field intensity at the edge of the RRAM cell 143 but makes the bottom electrode metal layer 123 more susceptible to damage by increasing the surface area that is exposed, and by increasing its exposure to damage by high energy particles projected along the vertical axis 138.

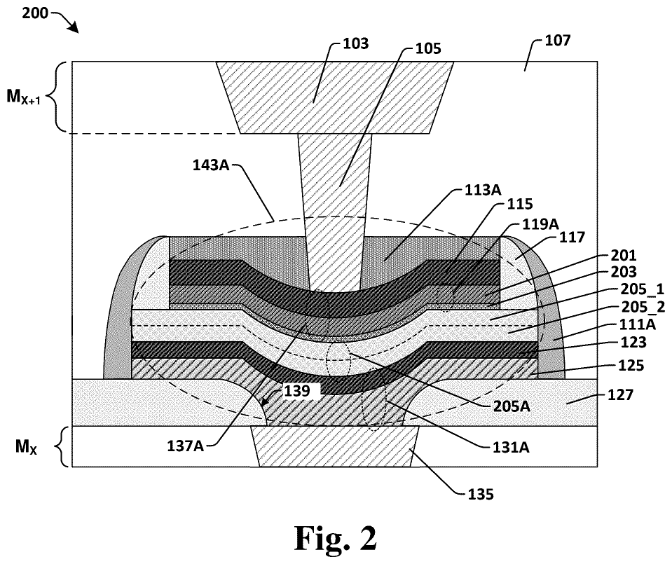

FIG. 2 illustrates a cross-sectional view of an integrated circuit device 200 that includes an RRAM cell 143A. The RRAM cell 143A has a top electrode 137A, a resistive switching structure 121A, a bottom electrode 131A, a hard mask 113A that is planarized, and a non-oxide dielectric layer 111A that has the profile of a sidewall-spacer. The RRAM cell 143A is similar to the RRAM cell 143 of FIG. 1 but has differences in geometry. The differences in geometry include the top electrode 137A and the bottom electrode 131A having vertical sidewalls. In addition, these sidewalls are displaced from the sidewalls 139 that define an opening in the dielectric layer 127 so that the top electrode 137A, the resistive switching structure 121A, and the bottom electrode 131A are planar in their peripheral areas.

The top electrode 137A has a capping structure 119A that includes a capping metal layer 201 and a diffusion barrier layer 203. The diffusion barrier layer 203 is a portion of the capping structure 119A that is provided to restrict or slow the transport of oxygen ions between the capping structure 119A to the resistive switching structure 121A, thereby mitigating spontaneous diffusion of oxygen ions that could adversely affect the stability of the RRAM cell 143A.

The resistive switching structure 121A has a layered structure that reduces the forming voltage. As transistors are made smaller, their safe operating voltages are reduced. Accordingly, the drive toward increasing integrated circuit device density has resulted in a long felt need to reduce the forming voltages for RRAM cells. One approach to reducing forming voltages is to reduce the thickness of the resistive switching structure, however, as the resistive switching structure becomes very thin (e.g., below 10 angstroms), there is a tendency for leakage currents to become excessive. In addition, as the resistive switching structure becomes thinner there is an increasing tendency for oxygen ions to spontaneously diffuse from the top electrode back into the resistive switching structure, which may negatively impact the reliability of the RRAM cell.

The resistive switching structure 121A solves this problem with a structure that includes a higher oxygen affinity metal oxide layer 205 and a lower oxygen affinity metal oxide layer 207. The higher oxygen affinity metal oxide layer 205 is proximate the top electrode 137A and the lower oxygen affinity metal oxide layer 207 is proximate the bottom electrode 131A. The difference in oxygen affinities causes some oxygen ions to spontaneously migrate from the lower oxygen affinity metal oxide layer 207 to the higher oxygen affinity metal oxide layer 205 and thereby create intrinsic oxygen vacancies in the lower oxygen affinity metal oxide layer 207. If the difference in oxygen affinities is sufficiently large and the thicknesses of the lower and higher oxygen affinity metal oxide layers 205 and 207 are suitably selected, the forming voltage will be lowered. To facilitate this mechanism, the bottom electrode 131A is designed to resist taking up or releasing oxygen.

The inventors observed that without the non-oxide dielectric layer 111A, the time required to switch from the LRS to the HRS would depend on the thickness of the bottom electrode 131A. The inventors found evidence of oxidative damage at the edges of the bottom electrode 131A and speculated that this damage was connected to the variation of switching time bottom electrode layer thickness. This speculation was confirmed by experiments showing that the addition of the non-oxide dielectric layer 111A cancels the dependency of switching times on thickness of the bottom electrode 131A and thereby enables the RRAM cell 143A to be made smaller without incurring a switching time penalty.

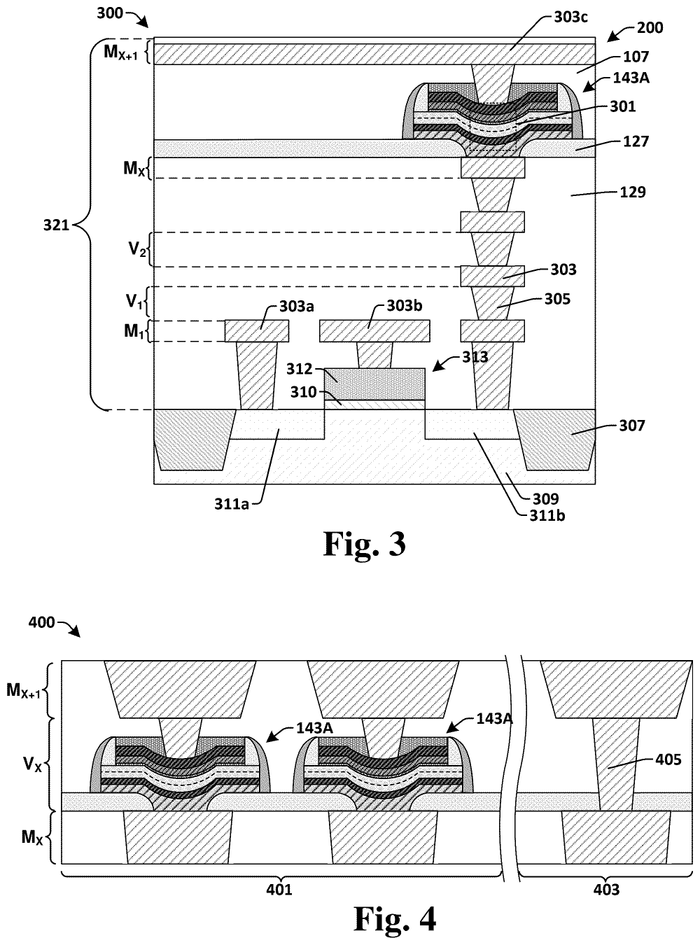

FIG. 3 provides a cross-sectional view 300 illustrating a larger portion of the integrated circuit device 200 of FIG. 2. The cross-sectional view 300 shows that the RRAM cell 143A is disposed within a metal interconnect structure 321 over a semiconductor substrate 309. A semiconductor device 313 at the surface of the semiconductor substrate 309 may provide an access control device for the RRAM cell 143A. The semiconductor device 313 is depicted as a metal-oxide semiconductor field-effect transistor (MOSFET) but could alternatively be a bipolar junction transistor (BTJ), a high-electric-mobility transistor (HEMT), the like, or some other type of access control device.

The semiconductor device 313 comprises a gate dielectric layer 310, a gate electrode 312, and a pair of source/drain regions 311a-b. An isolation structure 307 is disposed within the semiconductor substrate 309 and is configured to electrically isolate the semiconductor device 313 from other devices (not shown) disposed within and/or on the semiconductor substrate 309. Source/drain region(s) may refer to a source or a drain, individually or collectively depending on the context.

The metal interconnect structure 321 includes a plurality of metallization layers M₁, M_{X}, M_{X+1}, etc. separated by via layers V₁, V₂, etc. Each metallization layer comprising conductive traces 303 surrounded by inter-layer dielectric (ILD) 129. Each via layer comprising conductive vias 305 that interconnect the conductive traces 303 and are surrounded by the inter-layer dielectric (ILD) 129. The conductive traces 303 and the conductive vias 305 are electrically coupled in a predefined manner and configured to provide electrical connections between various devices disposed throughout the integrated circuit device 200.

A first conductive trace 303b electrically coupled to the gate electrode 312 may provide a wordline. A second conductive trace 303a electrically coupled to the source/drain region 311a may provide a source line. A third conductive trace 303c may provide a bit line. The RRAM cell 143A may be electrically coupled to the source/drain region 311b via the metal interconnect structure 321. Thus, in some embodiments, a suitable voltage applied to the word line electrically couples the RRAM cell 143A between the bit line and the source line. Accordingly, by providing suitable bias conditions, the RRAM cell 143A can be read or switched between one two distinct data states. A current through the RRAM cell 143A also passes through the semiconductor device 313. Designing the RRAM cell 143A to operate at lower voltages allows the semiconductor device 313 to be scaled down.

FIG. 4 provides a cross-sectional view 400 illustrating another larger portion of the integrated circuit device 200 of FIG. 2, this view showing that the RRAM cell 143A is one in an array of similar cells. The RRAM cells 143A may be in a memory region 401 of the semiconductor substrate 309 (see FIG. 3). The semiconductor substrate 309 may have a logic region 403 lateral to the memory region 401. The RRAM cells 143A may be within a via layer V_{X} containing vias 405 or elsewhere within the metal interconnect structure 321 (see FIG. 3).

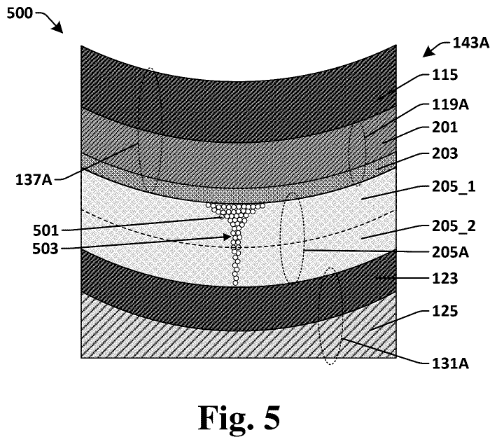

FIG. 5 provides a cross-sectional view 500 providing a more detailed view of the central area 301 of the RRAM cell 143A (see FIG. 3) after formation of a conductive filament 503 in the resistive switching structure 121A. In some embodiments, the conductive filament 503 comprises oxygen vacancies 501 and is formed and dissolved through redox reactions. Typically, initially forming the conductive filament 503 involves applying forming voltage pulses between the bottom and top electrodes 131A and 137A. Thereafter, set or reset voltages can be applied across bottom and top electrodes 131A and 137A to change a resistivity of the resistive switching structure 121A between the HRS and the LRS. The conductive filament 503 extends from the bottom electrode 131A to the capping structure 119A. Forming the conductive filament 503 produces the LRS. Dissolving at least a portion of the conductive filament 503 produces the HRS.

The forming voltage pulses can knock oxygen atoms from a lattice within the resistive switching structure 121A, thereby creating localized oxygen vacancies that tend to align and form the conductive filament 503. The capping structure 119A may be configured to absorb oxygen ions from the resistive switching structure 121A during forming and set operations and to release oxygen ions back into to the resistive switching structure 121A during reset operations. This role as an oxygen ion reservoir facilitates the formation and dissolution of the conductive filament 503. The diffusion barrier layer 203, positioned between the capping metal layer 201 and the higher oxygen affinity metal oxide layer 205, helps regulate the exchange of oxygen ions between. The bottom electrode metal layer 123 is designed to avoid releasing oxygen ions, as these would fill oxygen vacancies and counteract the filament formation process.

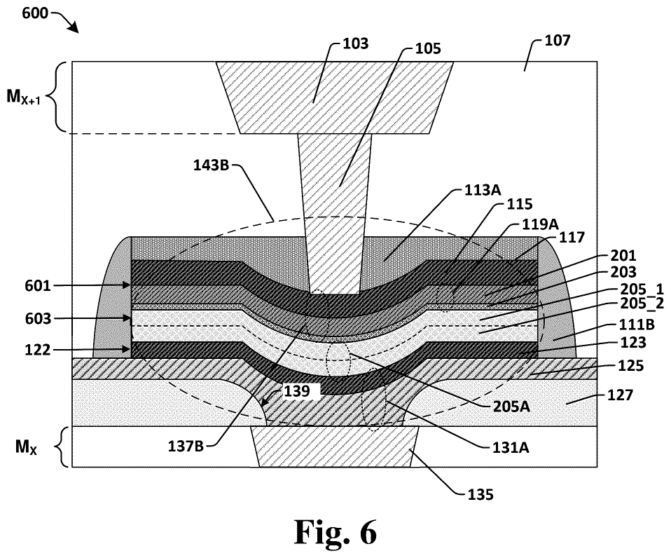

FIG. 6 illustrates a cross-sectional view of an integrated circuit device 600 that includes an RRAM cell 143B. The RRAM cell 143B is similar to the RRAM cell 143A of FIG. 2 but has a top electrode 137B having sidewalls 601 aligned with sidewalls 603 of the resistive switching structure 121A and sidewalls 122 of the bottom electrode metal layer 123. The sidewalls 601, 603, and 122 may be vertical or may taper away from the vertical axis. Non-oxide dielectric layer 111B covers and abuts the sidewalls 601, 603, and 122. In some embodiments, the non-oxide dielectric layer 111B has the profile of a sidewall spacer.

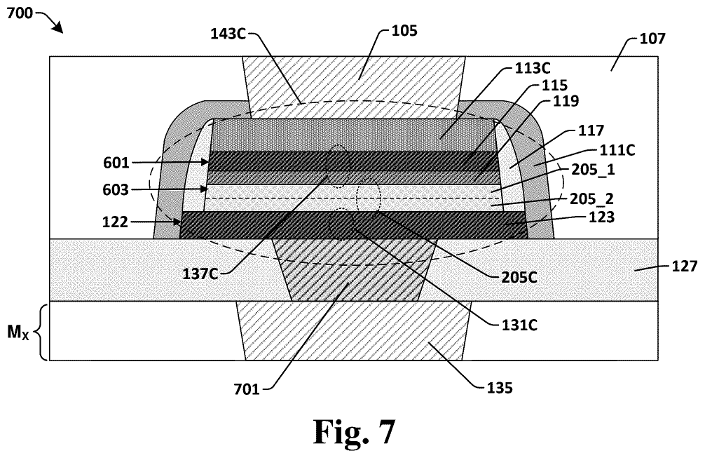

FIG. 7 illustrates a cross-sectional view of an integrated circuit device 700 that includes an RRAM cell 143C. The RRAM cell 143C is similar to the RRAM cell 143A of FIG. 2 but has a bottom electrode 131C, a resistive switching structure 121C, and a top electrode 137C that are planar. The bottom electrode 131C may be electrically coupled to the conductive trace 135 by a bottom electrode via 701. The bottom electrode via 701 is narrower than the bottom electrode 131C and may function as a diffusion barrier between the conductive trace 135 and the bottom electrode 131C. A non-oxide dielectric layer 111C covers and abuts the sidewall 122 of the bottom electrode metal layer 123, surrounds the sidewall spacer 117, and extends over the top electrode 137C and the hard mask 113C.

In embodiments that include the sidewall spacer 117, the sidewall spacer 117 may be disposed over the resistive switching structure 121, 121A, or 121C as shown in FIGS. 1 and 2, or may extend downward to the bottom electrode metal layer 123 as shown in FIG. 7 so that it covers the sidewall 603 of the resistive switching structure 121, 121A, or 121C. In either configuration the sidewall spacer 117 can prevent damage to an operative portion of the resistive switching structure 121 during etching of the bottom electrode metal layer 123.

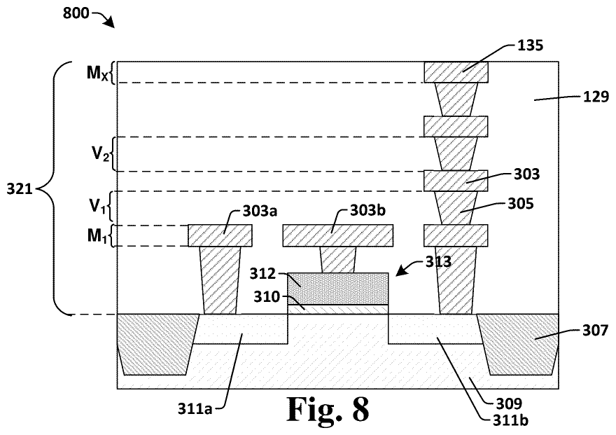

FIGS. 8-17 illustrate a series of cross-sectional views 800-1700 of an integrated circuit device comprising an RRAM cell at various stages of manufacture according to a process of the present disclosure. Although FIGS. 8-17 are described in relation to a series of acts, it will be appreciated that the order of the acts may in some cases be altered and that this series of acts are applicable to structures other than the ones illustrated. In some embodiments, some of these acts may be omitted in whole or in part. Furthermore, it will be appreciated that the structures shown in FIGS. 8-17 are not limited to a method of manufacture but rather may stand alone as structures separate from the method.

As illustrated in the cross-sectional view 800 of FIG. 8, the process may begin with front-end-of-line (FEOL) processing of the semiconductor substrate 309 followed by back-end-of-line processing that produces the metal interconnect structure 321 up to the metallization layer M_{X}. The semiconductor substrate 309 may be or comprise, for example, silicon, monocrystalline silicon, silicon-germanium, a silicon-on-insulator (SOI) substrate, one or more epitaxial layers, some other suitable substrate or any combination of the foregoing. FEOL processing provides isolation structures 307, doped substrate regions such as the source/drain regions 311a-b, and semiconductor devices such as the semiconductor device 313.

BEOL processing includes forming layers of the inter-layer dielectric 129 and optionally etch stop layers (not shown) between layers. The inter-layer dielectric 129 may be or comprise silicon dioxide (SiO₂), a low-k dielectric, or an extremely low-k dielectric. A low-k dielectric is one having a smaller dielectric constant than silicon dioxide (SiO₂). SiO₂ has a dielectric constant of about 3.9. Examples of low-k dielectrics include organosilicate glasses (OSG) such as carbon-doped silicon dioxide, fluorine-doped silicon dioxide (otherwise referred to as fluorinated silica glass (FSG), organic polymer low-k dielectrics, and porous silicate glass. An extremely low-k dielectric is a material having a dielectric constant of about 2.1 or less. An extremely low-k dielectric material is generally a low-k dielectric material formed into a porous structure. Porosity reduces the effective dielectric constant. The inter-layer dielectric 129 may be deposited by atomic layer deposition (ALD), chemical vapor deposition (CVD), physical vapor deposition (PVD), the like, or any other suitable processes.

Conductive vias 305 and conductive traces 303 may be formed within the inter-layer dielectric 129 by damascene or dual damascene processes. Conductive vias 305 and conductive traces 303 may be or comprise, for example, copper (Cu), aluminum (Al), tungsten (W), ruthenium (Ru), a combination of the foregoing, or the like. In some embodiments, a diffusion barrier layer 133 (see FIG. 1) separates the conductive vias 305 and conductive traces 303 from the inter-layer dielectric 129. The diffusion barrier layer 133 may be or comprise, for example, titanium nitride (TiN), tantalum nitride (TaN), or the like. The damascene or dual damascene process may comprise masking and etching to form trenches and holes, deposition to fill the trenches and holes, followed by planarization, e.g., chemical mechanical polishing (CMP), to remove excess material. The deposition process may be, for example, ALD, CVD, electroplating, electroless plating, or the like.

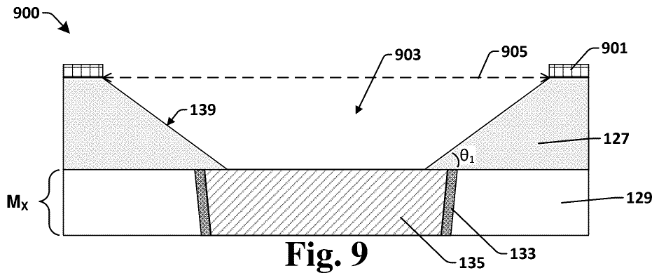

As shown by the cross-sectional view 900 of FIG. 9, the dielectric layer 127 may be deposited over the metallization layer M_{X}, a mask 901 may be formed, and the dielectric layer 127 etched to form the hole 903 with sidewalls 139. The dielectric layer 127 may be or comprise, for example, silicon dioxide (SiO₂), silicon carbide (SiC), silicon oxycarbide (SiOC), silicon nitride (SiN), silicon oxynitride (SiON), boron nitride (BN), aluminum nitride (AlN), the like, some other dielectric material, or any combination of the foregoing. In some embodiments, the dielectric layer 127 is a non-oxide dielectric such silicon carbide (SiC), silicon nitride (SiN), silicon carbonitride (SiCN), boron nitride (BN), aluminum nitride (AlN), or the like. Use of a non-oxide dielectric may help maintain the bottom electrode 131 (see FIG. 1) free of oxygen. In some embodiments, the dielectric layer 127 is a carbide-based dielectric, such as silicon carbide (SiC), or some other dielectric that provides an effective barrier to copper diffusion.

The mask 901, as well as other masks utilized in the processes described herein, may comprise a photoresist, a hard mask, or similar materials. The mask 901 and other masks employed in these processes may be patterned using photolithography, ion beam lithography, or another suitable patterning technique. The etching process may be a dry etch, such as a plasma etch, or another appropriate etching method. The etching process may be configured to form the hole 903 with sidewalls 139 at the angle θ₁ by adjusting parameters such as the etchant gas composition, pressure, power, angle of incidence, and etching time. Following the etching process, the mask 901 may be removed.

The width 905 of the hole 903, the thickness of the dielectric layer 127, and the angle θ₁ at which the sidewalls 139 taper will each affect the shape of the resulting RRAM cell 143 (see FIG. 1). In some embodiments, the thickness of the dielectric layer 127 is in the range from about 50 Å to about 1000 Å. In some embodiments, the thickness of the dielectric layer 127 is in the range from about 100 Å to about 400 Å. In some embodiments, the width 905 is in the range from about 5 nm to about 200 nm. In some embodiments, the width 905 is in the range from about 10 nm to about 100 nm.

In some embodiments, an aspect ratio of the hole 903 (ratio of the width 905 to the thickness of the dielectric layer 127) is in the range from about 1:1 to about 5:1.

The angle θ₁ may be relatively small, reflecting that the sidewall 139 tapers at a shallow angle. In some embodiments, the angle θ₁ is in the range from about 10° to about 80°. In some embodiments, the angle θ₁ is in the range from about 30° to about 60°. If the angle θ₁ is too small or too large, an RRAM cell shaped by the hole 903 may have reduced reliability.

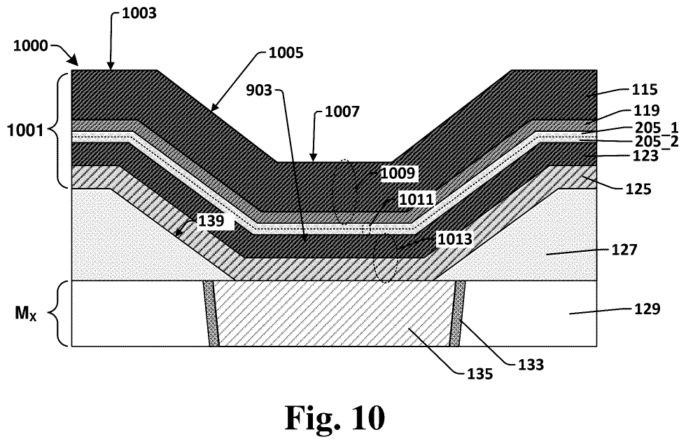

As shown by the cross-sectional view 1000 of FIG. 10, an RRAM cell stack 1001 is formed over the hole 903. The RRAM cell stack 1001 is formed using conformal or partially conformal deposition processes, resulting in a central depression 1007 over the hole 903, and a tapered area 1005 extending from the central depression 1007 to an outer region 1003. In some embodiments, the tapered area 1005 has a slope similar to the sidewall 139 of the hole 903.

The RRAM cell stack 1001 includes bottom electrode layers 1013, resistive switching layers 1011, and top electrode layers 1009. The bottom electrode layers 1013 may include the barrier layer 125 and the bottom electrode metal layer 123. In some embodiments, the bottom electrode metal layer 123 has a composition selected to not significantly absorb oxygen ions from or release oxygen ions to the resistive switching layers 1011. In some embodiments, the barrier layer 125 is selected to be a conductive material that blocks copper diffusion. The barrier layer 125 may be, for example, and a conductive oxide, nitride, or oxynitride of aluminum (Al), manganese (Mn), cobalt (Co), titanium (Ti), tantalum (Ta), tungsten (W), nickel (Ni), tin (Sn), magnesium (Mg), a combination thereof, or the like. The bottom electrode metal layer 123 may be copper (Cu), ruthenium (Ru), aluminum (Al), tungsten (W), tantalum (Ta), titanium (Ti), a compound or mixture therefor, or the like. The composition of the bottom electrode metal layer 123 may be selected to provide a good work function match to the adjacent resistive switching layer 1011. In some embodiments, a thickness of the bottom electrode metal layer 123 is in the range from about 3 Angstroms to about 500 Angstroms. In some embodiments, the thickness is in the range from about 50 Angstroms to about 100 Angstroms.

The resistive switching layers 1011 may be one or more layers of suitable dielectrics. Dielectrics that may be suitable include hafnium oxide (HfO), zirconium oxide (ZrO), aluminum oxide (AlO), silicon nitride (SiN), aluminum nitride (AlN), other high-k dielectrics, and the like. In some embodiments, the resistive switching layers 1011 are metal oxides. In some embodiments, the resistive switching layers 1011 include a higher oxygen affinity metal oxide layer 205 and a lower oxygen affinity metal oxide layer 207.

The higher oxygen affinity metal oxide layer 205 and the lower oxygen affinity metal oxide layer 207 differ in the oxygen affinities of their metals. One measure of the oxygen affinity of a metal is the standard Gibbs free energy of oxygen vacancy formation for a maximum oxide (the oxide with the highest proportion of oxygen) of the metal. A higher standard Gibbs free energy oxygen vacancy formation indicates greater oxygen affinity. A practically equivalent and more tractable measure is the standard Gibbs free energy of formation of the maximum oxide on a per mole oxygen basis. A lower (more negative) standard Gibbs free energy of metal oxide formation indicates greater oxygen affinity. In some embodiments, a difference in standard Gibbs free energy of metal oxide formation of a first metal, which is the metal of the lower oxygen affinity metal oxide layer 207, and the standard Gibbs free energy of metal oxide formation of a second metal, which is the metal of the higher oxygen affinity metal oxide layer 205, is at least about 100 kJ/mol oxygen (O₂). In some embodiments, the difference is at least about 200 kJ/mol oxygen (O₂).

In some embodiments, a ratio of thicknesses between the lower oxygen affinity metal oxide layer 207 and the higher oxygen affinity metal oxide layer 205 is in the range from about 0.5 to about 1.3. In some embodiments, the thicknesses ratio is in the range from about 0.8 to about 1.0. In some embodiments, a thickness of the resistive switching layers 1011 is in the range from about 20 angstroms to about 45 angstroms. In some embodiments, each of the lower oxygen affinity metal oxide layer 207 and the higher oxygen affinity metal oxide layer 205 has a thickness of at least about 10 angstroms. If the higher oxygen affinity metal oxide layer 205 is too thin, or too thin relative to the lower oxygen affinity metal oxide layer 207, it may not have the capacity to create a sufficient number of oxygen vacancies in the lower oxygen affinity metal oxide layer 207 to appreciably lower the forming voltage. If the higher oxygen affinity metal oxide layer 205 is too thick, it may increase the forming voltage. If the lower oxygen affinity metal oxide layer 207 is too thin, it may not be able to hold enough oxygen vacancies to appreciably lower the forming voltage. If the lower oxygen affinity metal oxide layer 207 and the higher oxygen affinity metal oxide layer 205 combined are too thin, leakage currents may be excessive.

In some embodiments, the higher oxygen affinity metal oxide layer 205 is or comprises an oxide of a metal having a standard Gibbs free energy of oxide formation of −1000 kJ/mol O₂ or lower. In some embodiments, the higher oxygen affinity metal oxide layer 205 is or comprises one of zirconium oxide (ZrO), lanthanum oxide (LaO), hafnium oxide (HfO), gadolinium oxide (GdO), yttrium oxide (YO), or the like. In some embodiments, the higher oxygen affinity metal oxide layer 205 has a thickness in the range from about 10 angstroms to about 25 angstroms.

In some embodiments, the lower oxygen affinity metal oxide layer 207 comprises an oxide of a metal having a standard Gibbs free energy of oxide formation of about −900 kJ/mol O₂ or higher. In some embodiments, the lower oxygen affinity metal oxide layer 207 comprises an oxide of a metal having a standard Gibbs free energy of oxide formation in the range from about −750 kJ/mol O₂ (that of tantalum) to about −500 kJ/mol O₂. If the oxygen affinity of the lower oxygen affinity metal oxide layer 207 is too high, then it may not be possible to form intrinsic oxygen vacancies and lower the forming voltage. If the oxygen affinity of the lower oxygen affinity metal oxide layer 207 is too low, then leakage current may become excessive. In some embodiments, the lower oxygen affinity metal oxide layer 207 comprises one of zinc oxide (ZnO), tantalum oxide (TaO), silicon oxide (SiO), germanium oxide (GeO), indium tin oxide (ITO), indium gallium zinc oxide (IGZO), ruthenium oxide (RuO), or the like.

Indium tin oxide (ITO) has a standard Gibbs free energy of formation of about −550 kJ/mol O₂. Indium gallium zinc oxide (IGZO) has a standard Gibbs free energy of formation of about −620 kJ/mol O₂.

In some embodiments, the lower oxygen affinity metal oxide layer 207 has a thickness in the range from about 10 angstroms to about 25 angstroms. The difference in oxygen affinity between the lower oxygen affinity metal oxide layer 207 and the higher oxygen affinity metal oxide layer 205 is sufficient to cause oxygen ions to spontaneously migrate from the lower oxygen affinity metal oxide layer 207 to the higher oxygen affinity metal oxide layer 205, creating intrinsic oxygen vacancies in the lower oxygen affinity metal oxide layer 207 to an extent that reduces a forming voltage for the RRAM cell 143.

The number of intrinsic oxygen vacancies in the lower oxygen affinity metal oxide layer 207 depends on the relative thicknesses of the higher oxygen affinity metal oxide layer 205. In some embodiments, a ratio of the thickness of the higher oxygen affinity metal oxide layer 205 to the thickness of the lower oxygen affinity metal oxide layer 207 is 0.85 or greater. In some embodiments, the ratio is 1:1 or greater. These ratios provide the higher oxygen affinity metal oxide layer 205 with the capacity to receive a sufficient numbers of oxygen ions from the lower oxygen affinity metal oxide layer 207 and create a sufficient number of oxygen vacancies to realize the desired reduction in forming voltage.

In some embodiments, the lower oxygen affinity metal oxide layer 207 further comprises a dopant metal oxide. The dopant metal oxide increases endurance by limiting the dispersion of oxygen vacancies that may occur over many cycles of forming and disrupting the conductive filament 503 (see FIG. 5). The metal having the higher concentration in the lower oxygen affinity metal oxide layer 207 may then be referred to as the bulk metal. The concentration of the dopant metal may be sufficiently low that the overall oxygen affinity of the lower oxygen affinity metal oxide layer 207 is not substantially altered by the dopant metal. The dopant metal has a higher oxygen affinity than the bulk metal. In some embodiments, the dopant metal has a standard Gibbs free energy of oxide formation of less than about −750 kJ/mol O₂ (less than that of tantalum).

For purposes of the present disclosure, including determining which is the bulk metal and which is the dopant metal in the foregoing embodiments, the following standard Gibbs free energies of oxide formation expressed in kJ/mol oxygen (O₂) may be used: ruthenium (Ru, −274), zinc (Zn, −640), tantalum (Ta, −750), silicon (Si, −860), titanium (Ti, −889), hafnium (Hf, −1000), aluminum (Al, −1055), zirconium (Zr, −1100), lanthanum (La, −1140), neodymium (Nd, −1150), gadolinium (Gd, −1160), yttrium (Y, −1270).

In some embodiments, the lower oxygen affinity metal oxide layer 207 has a sub-stoichiometric amount of oxygen with respect to the maximum oxides of its metal constituents. In some embodiments, the oxygen amount is in the range from about 80 to about 99.5% of the stoichiometric amount. In some embodiments, the oxygen amount is in the range from about 90 to about 95% of the stoichiometric amount. A sub-stoichiometric amount of oxygen lowers the forming voltage. If the oxygen amount is too high, the forming voltage may be too high. If the oxygen amount is too low, leakage currents may be excessive.

In some embodiments, the lower oxygen affinity metal oxide layer 207 has a dopant concentration in the range from 0.1% to about 10% on an atomic basis. If the dopant amount is too low, the benefit of improved endurance may not be realized. If the dopant amount is too high, the forming voltage may increase excessively.

In some embodiments, the higher oxygen affinity metal oxide layer 205 has a sub-stoichiometric amount of oxygen with respect to the maximum oxides of its metal constituents. In some embodiments, the oxygen amount is in the range from about 80 to about 99.5% of the stoichiometric amount. In some embodiments, the oxygen amount is in the range from about 90 to about 95% of the stoichiometric amount. A sub-stoichiometric amount of oxygen in the higher oxygen affinity metal oxide layer 205 also contributes to realizing a lower forming voltage. If the oxygen amount in the higher oxygen affinity metal oxide layer 205 is too high, the forming voltage may be too high. If the oxygen amount in the higher oxygen affinity metal oxide layer 205 is too low, leakage currents may be excessive.

The resistive switching layers 1011 may be formed by CVD, PVD, ALD, the like, or any other process(es). In some embodiments, these layers are formed by ALD. In some embodiments, the lower oxygen affinity metal oxide layer 207 includes a dopant metal oxide and the dopant metal oxide is deposited in separate cycles from the bulk metal oxide. It has been found that the lower oxygen affinity metal oxide layer performs better if the dopant metal is deposited in separate cycles as opposed to if the dopant metal precursor is combined with the bulk metal precursor so that both metal oxides deposit simultaneously. In some embodiments, a ratio of bulk metal oxide to dopant metal oxide deposition cycles is in the range from 3:1 to 15:1. In some embodiments, a ratio of bulk metal oxide to dopant metal oxide deposition cycles is in the range 5:1 to 10:1. In some embodiments, a ratio of bulk metal oxide to dopant metal oxide deposition cycles is at least 6:1. If the ratio is too low, the forming voltage may increase. If the ratio is too high, there may not be enough dopant metal to improve endurance.

The top electrode layers 1009 include a capping structure 119 and a top electrode metal layer 115. In some embodiments, the capping structure 119 comprises one or more layers of metals with high oxygen ion solubility such as tantalum (Ta), titanium (Ti), platinum (Pt), aluminum (Al), hafnium (Hf), zirconium (Zr), nickel (Ni), iridium (Ir), or the like. In some embodiments, a diffusion barrier layer 203 (see FIG. 2) is provided to reduce spontaneous diffusion of oxygen ions from the capping structure 119 to the resistive switching layers 1011. The diffusion barrier layer 203 may be of comprise, for example, tantalum nitride (TaN), titanium nitride (TiN), or the like. In some embodiments, the diffusion barrier layer 203 is a metal nitride of the capping structure 119. A thickness of the diffusion barrier layer 203 may be in the range from about 20 Angstroms to about 30 Angstroms. If the diffusion barrier layer 203 is too thin, it may allow excessive spontaneous diffusion of oxygen ions. If the diffusion barrier layer 203 is too thick, it may increase the forming voltage excessively.

A thickness of the capping structure 119 may be within a range from about 10 Angstroms to about 50 Angstroms or some other suitable value. If the capping structure 119 is too thin, the capping structure 119 may not adequately absorb oxygen ions during set operations. If the capping structure 119 is too thick, oxygen ions may become dispersed in the capping structure 119 and not return to the resistive switching layers 1011 during reset operations.

The top electrode metal layer 115 has good conductivity but need not absorb oxygen significantly. The top electrode metal layer 115 may be, for example, tantalum nitride (TaN), titanium nitride (TiN), ruthenium (Ru), platinum (Pt), a combination thereof, or the like. A thickness of the top electrode metal layer 115 may be, for example, within a range from about 80 Angstroms to about 200 angstroms or some other suitable value. The top electrode layers 1009 may be formed by CVD, PVD, ALD, electroplating, electroless plating, a combination thereof, or the like.

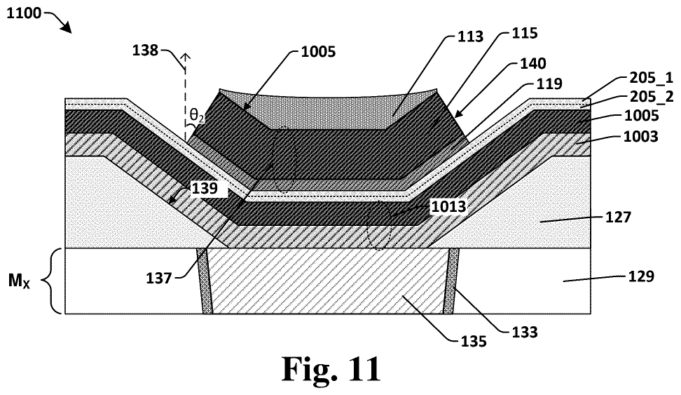

As illustrated in the cross-sectional view 1100 of FIG. 11, the hard mask 113 is formed and used to pattern the top electrode metal layer 115 and the capping structure 119 to define the top electrode 137. Optionally, the etch continues through the higher oxygen affinity metal oxide layer 205 and the lower oxygen affinity metal oxide layer 207 to form the sidewall 140 define the resistive switching structure. In some embodiments, the sidewall 140 is formed in the tapered area 1005, wherein the top electrode 115 has a taper corresponding to the sidewall 139. The etching process may be a dry etch, such as a plasma etch, or another appropriate etching method. The etching process may be configured to form the sidewall 140 at the angle θ₂ by adjusting parameters such as the etchant gas composition, pressure, power, and etching time.

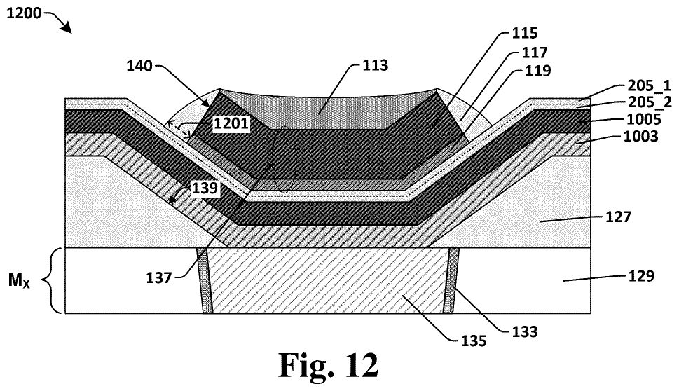

As illustrated in the cross-sectional view 1200 of FIG. 12, the sidewall spacer 117 is formed so as to be disposed over the bottom electrode layers 1013 and to cover the sidewall 140 of the top electrode 137. The width 1201 of the sidewall spacer 117 may be, for example, in the range from about 10 Angstroms to about 200 Angstroms.

The sidewall spacer 117 may be or comprise, for example, silicon dioxide (SiO₂), silicon carbide (SiC), silicon oxycarbide (SiOC), silicon nitride (SiN), silicon oxynitride (SiON), or the like. In some embodiments, the sidewall spacer 117 is a non-oxide dielectric such silicon carbide (SiC), silicon nitride (SiN), silicon carbonitride (SiCN), or the like.

The sidewall spacer 117 may be fabricated through deposition and etching. The deposition process may be, for example, CVD, PVD, ALD, or the like. Etching may remove spacer material that is over the top electrode 137. The etch process may be an anisotropic plasma etch, the like, or some other suitable etch process.

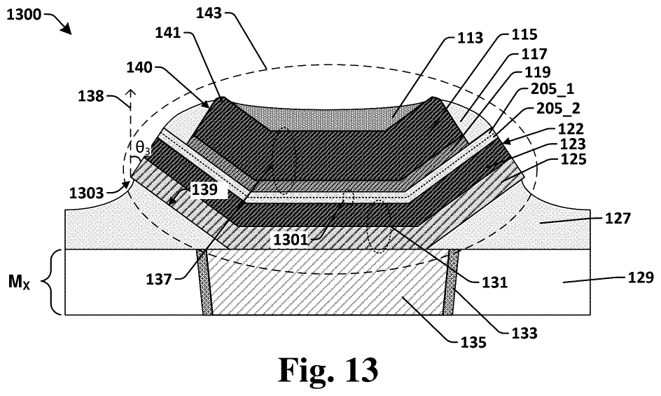

As illustrated in the cross-sectional view 1300 of FIG. 13, a second etch process is carried out, this one aligned by the sidewall spacer 117 together with the hard mask 113. The second etch process defines the resistive switching structure 1301, if not defined already by the first etch process, and defines the bottom electrode 131. The etching process may be a dry etch, such as a plasma etch, or another appropriate etching method. The etching process may be configured to form the sidewall 122 at the angle θ₃ by adjusting parameters such as the etchant gas composition, pressure, power, and etching time. In some embodiments, the second etch process exposes the corners 141 by recessing the hard mask 113 or otherwise. In some embodiments, the second etch process recesses the dielectric layer 127 and produces an undercut 1303 at the edge of the bottom electrode 131. The second etch process completes the definition of the RRAM cell 143 from the RRAM cell stack 1001 (see FIG. 10).

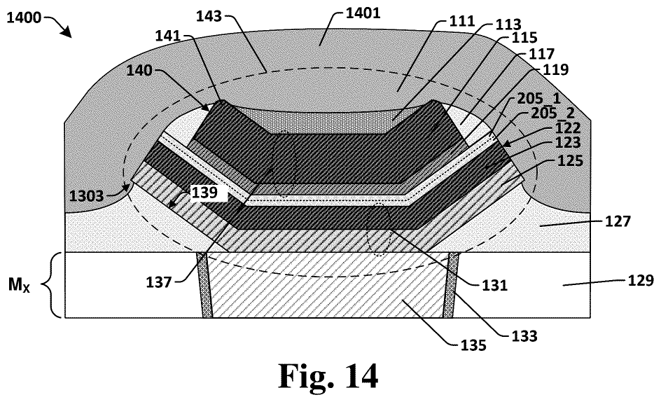

As illustrated in the cross-sectional view 1400 of FIG. 14, non-oxide dielectric material 1401 is deposited over the RRAM cell 143 so as to cover the sidewall 122 and the corner 141. In some embodiments, the partially manufactured device illustrated in the cross-sectional view 1300 of FIG. 13 is maintained in a substantially oxygen-free environment up until and continuing through the deposition of the non-oxide dielectric material 1401 so that native oxides do not form on the exposed metals. The non-oxide dielectric material 1401 may be deposited by CVD, PVD, ALD, the like, or any other suitable process. In some embodiments, the deposition process takes place in an oxygen-free environment.

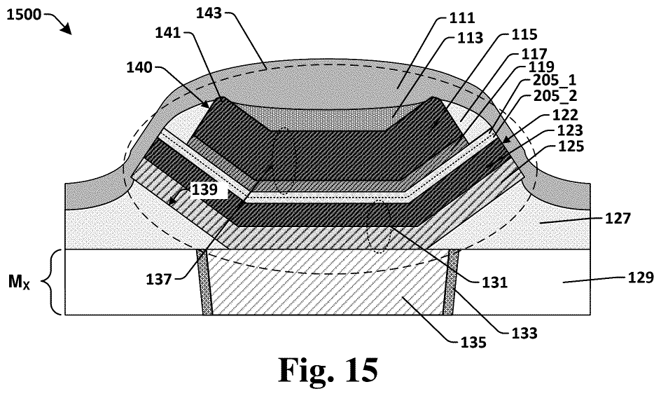

As illustrated in the cross-sectional view 1500 of FIG. 15, the non-oxide dielectric material 1401 may be etched to define the non-oxide dielectric layer 111. In some embodiments, the non-oxide dielectric material 1401 is deposited only to its final thickness and this etch process may be omitted, but the combination of deposition and etching has advantages such as gap filling. The etch process may be a dry etch, a wet etch, or any other suitable etch process. In some embodiments, etching leaves the non-oxide dielectric layer 111 extending over the RRAM cell 143.

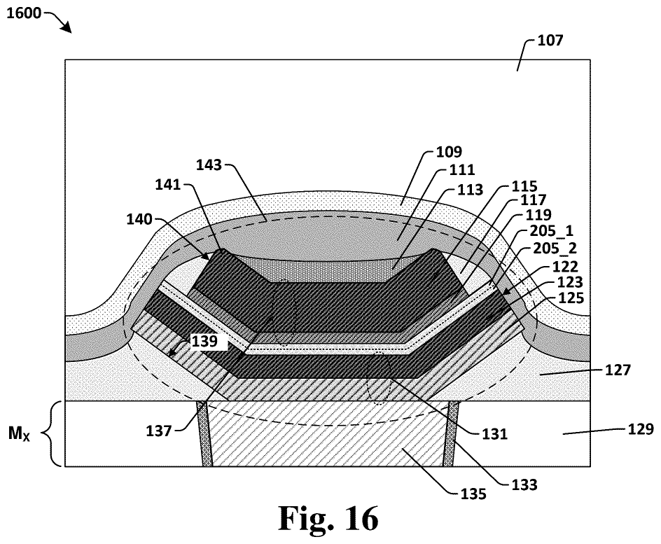

As illustrated in the cross-sectional view 1600 of FIG. 16, the inter-layer dielectric 107 may be deposited over the RRAM cell 143. In some embodiments, the interfacial layer 109 is deposited prior to the deposition of the inter-layer dielectric 107. The respective layers may be deposited by CVD, PVD, ALD, or some other suitable deposition or growth process. In some embodiments, the inter-layer dielectric 107 dielectric is deposited via plasma-enhanced CVD utilizing a feed gas comprising tetraethyl orthosilicate (TEOS) and oxygen (O₂). In such embodiments, the oxygen is ordinarily introduced prior to the introduction of the TEOS to prepare the surface; however, this step may be omitted if the interfacial layer 109 is deposited beforehand.

In some embodiments, the inter-layer dielectric 107 is a low-k dielectric. In some embodiments, the inter-layer dielectric 107 is an extremely low-k dielectric. Deposition parameters may be adjusted, and/or additional feed gases may be introduced, to achieve the desired low-k or extremely low-k dielectric properties. The non-oxide dielectric layer 111 protects the bottom electrode 131 from oxidative damage during these deposition processes.

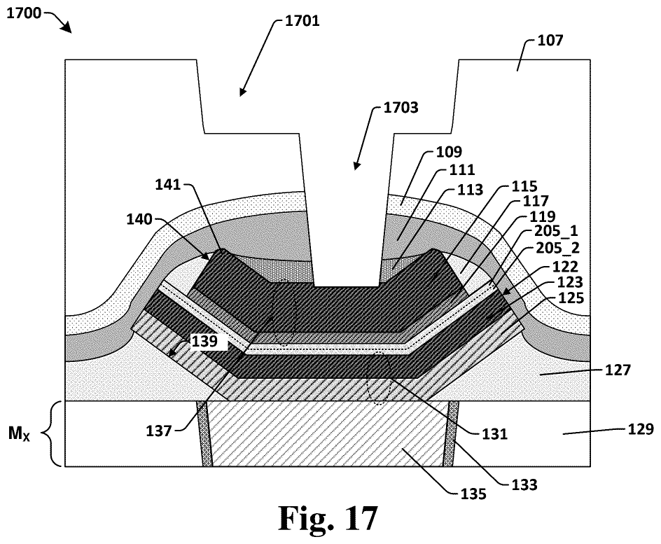

As illustrated in the cross-sectional view 1700 of FIG. 17, openings may be formed in the inter-layer dielectric 107. These openings may include a trench 1701 and a hole 1703. The hole 1703 extends through the inter-layer dielectric 107, through the interfacial layer 109, and through the hard mask 113, thereby exposing the top electrode 137. The openings may be formed using a masking and etching process, which may be either a trench-first or via-first process. The trench 1701 and the hole 1703 may be lined with a diffusion barrier layer 101 and subsequently filled with conductive material to provide a conductive trace 103 and a via 105, as depicted in FIG. 1. The conductive material may be deposited by CVD, PVD, ALD, electroless plating, electroplating, or any other suitable deposition process. Following deposition, excess material may be removed using a planarization process such as CMP or the like.

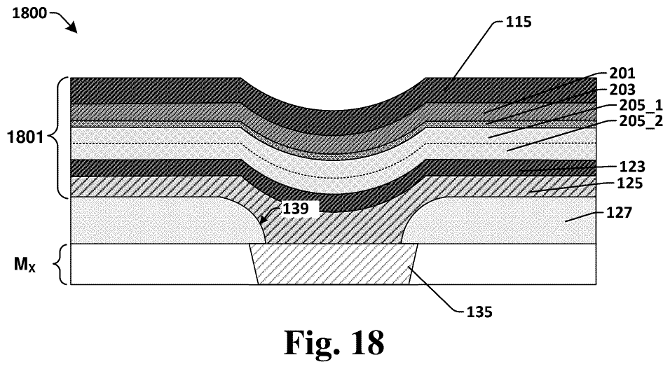

FIGS. 18-23 illustrate a series of cross-sectional views 1800-2300 of an integrated circuit device comprising an RRAM cell at various stages of manufacture according to another process of the present disclosure. Although FIGS. 18-23 are described in relation to a series of acts, it will be appreciated that the order of the acts may in some cases be altered and that this series of acts are applicable to structures other than the ones illustrated. In some embodiments, some of these acts may be omitted in whole or in part. Furthermore, it will be appreciated that the structures shown in FIGS. 18-23 are not limited to a method of manufacture but rather may stand alone as structures separate from the method.

The process illustrated by FIGS. 18-23 is in many ways similar to the process illustrated by FIGS. 8-17. The process of FIGS. 18-23 may have the same steps as the process of FIGS. 8-17 through the formation of the RRAM cell stack 1801 shown in the cross-sectional view 1800 of FIG. 18. The RRAM cell stack 1801 may be substantially the same as the RRAM cell stack 1001 of FIG. 10, although the RRAM cell stack 1801 is depicted as having a slightly differ shape.

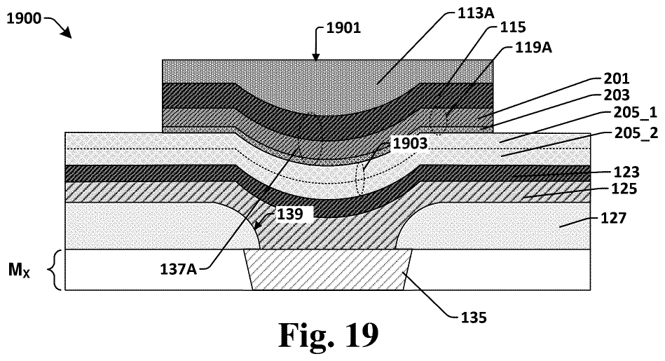

As illustrated by the cross-sectional view 1900 of FIG. 19, the hard mask 113A is formed, and the first etch process is performed to define the top electrode 137A. This process is similar to the one illustrated by the cross-sectional view 1100 of FIG. 11, except that the hard mask 113A is made to have a planar upper surface 1901, and the top electrode 137A is etched to have vertical sidewalls. The first etch process may stop on the resistive switch layers 1903, within the resistive switch layers 1903, or on the bottom electrode metal layer 123.

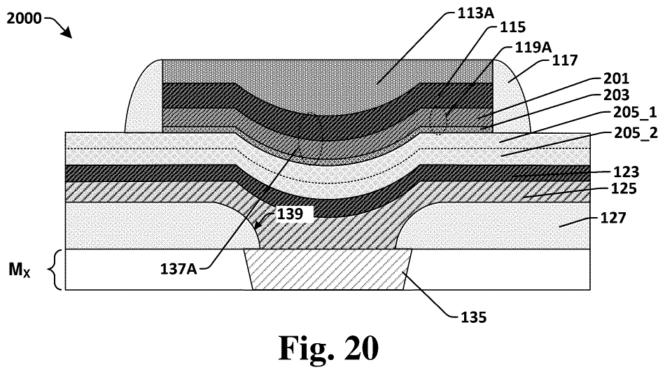

As illustrated by the cross-sectional view 2000 of FIG. 20, the sidewall spacer 117 is formed around sidewalls of the top electrode 137A and the hard mask 113A. The process may be similar to the one illustrated by the cross-sectional view 1200 of FIG. 12.

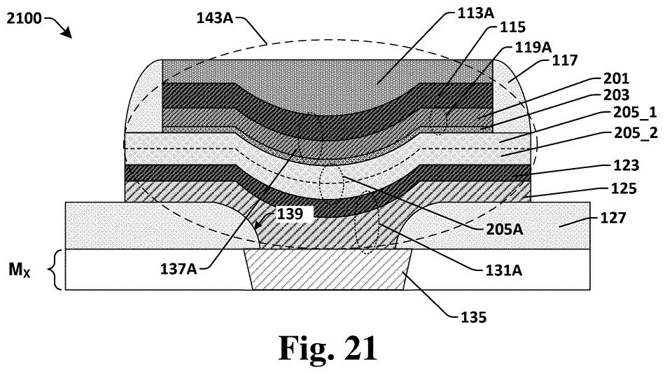

As illustrated by the cross-sectional view 2100 of FIG. 21, the second etch process is carried out to define the bottom electrode 131A, define the resistive switching structure 121A, and complete the formation of the RRAM cell 143A. The process may be similar to the one illustrated by the cross-sectional view 1300 of FIG. 13 except that the etch process is designed to provide the bottom electrode 131A and the resistive switching structure 121A with vertical sidewalls.

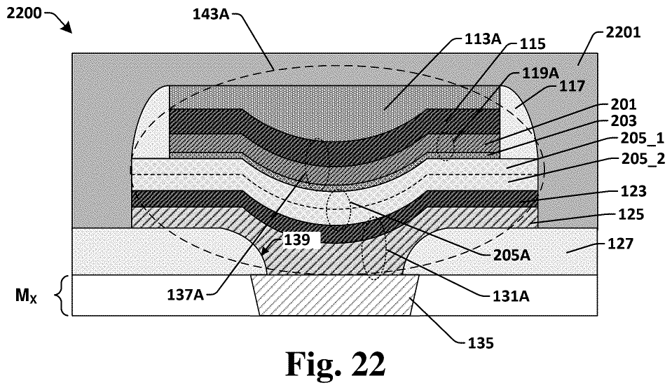

As illustrated by the cross-sectional view 2200 of FIG. 22, non-oxide dielectric material 2201 may be deposited over the RRAM cell 143A. The process may be similar to the one illustrated by the cross-sectional view 1400 of FIG. 14.

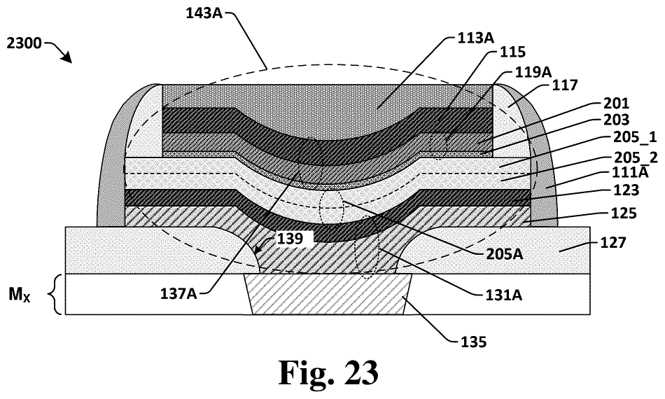

As illustrated by the cross-sectional view 2300 of FIG. 23, an etch process may be carried out to define the non-oxide dielectric layer 111A from the non-oxide dielectric material 2201. The process may be similar to the one illustrated by the cross-sectional view 1500 of FIG. 15, except that the etch process removes the non-oxide dielectric material 2201 from above the hard mask 113A and the top electrode 137A. The etch process may leave the non-oxide dielectric layer 111A with the tapered profile of a sidewall spacer. The process may then proceed as depicted in the cross-sectional view 1600 and 1700 of FIGS. 16 and 17 to provide an integrated circuit device like the one shown in FIG. 2.

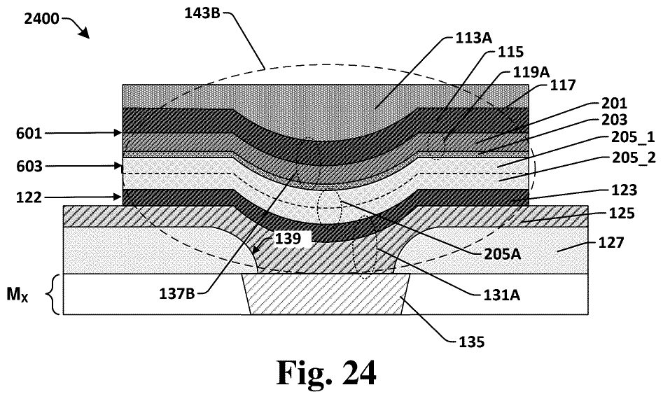

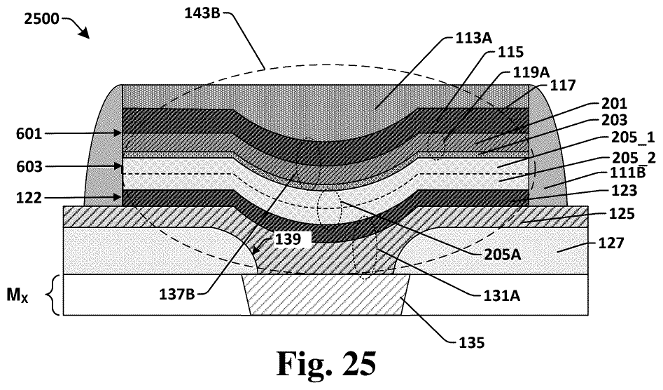

The cross-sectional views 2400 and 2500 of FIGS. 24 and 25 illustrate a variation of the foregoing process that may be employed to form the integrated circuit device 600 of FIG. 6. This variation begins with the second etch process. As shown by the cross-sectional view 2400 of FIG. 24, the first etch process, previously illustrated with the cross-sectional view 1900 of FIG. 19, may be combined with the second etch process and extend through the bottom electrode metal layer 123 to define the RRAM cell 143B. In this embodiment, the sidewall 601 of the top electrode 137B, sidewall 603 of the resistive switching structure 121A, and sidewall 122 of the bottom electrode metal layer 123 are aligned. The second etch process may extend through to the dielectric layer 127 or terminate on the barrier layer 125, as depicted in FIG. 24. Termination of the second etch process on the barrier layer 125 may mitigate damage to the sidewall 122 of the bottom electrode metal layer 123. The barrier layer 125 may be relatively thin and have relatively low conductivity, rendering etching through this layer unnecessary.

As illustrated in the cross-sectional view 2500 of FIG. 25, the non-oxide dielectric layer 111B may be formed around the RRAM cell 143B and take the shape of a sidewall spacer. This process may correspond to the one described in connection with the cross-sectional views 2200 and 2300 of FIGS. 22 and 23. In this variation, the formation of the sidewall spacer 117 as depicted in the cross-sectional view 2000 of FIG. 20 may be omitted, allowing the non-oxide dielectric layer 111B to directly abut both the sidewall 601 of the top electrode 137B and the sidewall 122 of the bottom electrode metal layer 123.

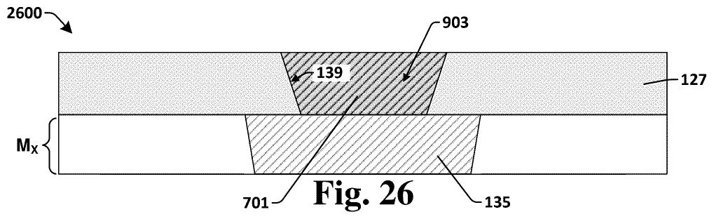

The cross-sectional views 2600-3100 of FIGS. 26-31 illustrate a process according to another embodiment that may be employed to form the integrated circuit device 700 of FIG. 7. The process may begin with a structure as shown by the cross-sectional view 900 of FIG. 9. As illustrated in the cross-sectional view 2600 of FIG. 26, conductive material is deposited so as to fill the hole 903 followed by planarization to form the bottom electrode via 701. The deposition process may be CVD, PVD, ALD, electroless plating, electroplating, or the like. The planarization process may be CMP or the like.

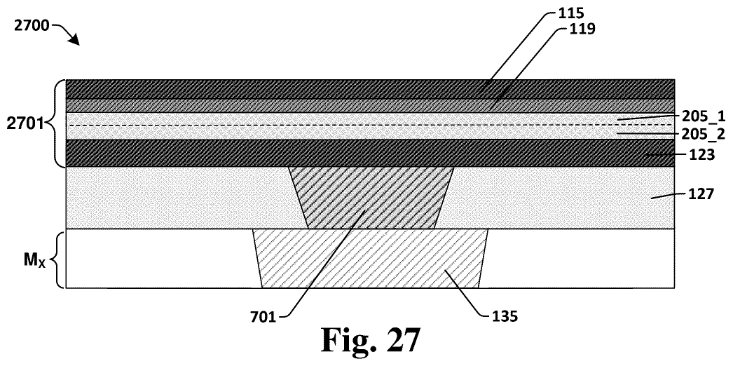

As depicted in the cross-sectional view 2700 of FIG. 27, the RRAM cell stack 2701 may be deposited over the bottom electrode via 701. The RRAM cell stack 2701 may be similar to the RRAM cell stack 1001 of FIG. 10 and may be formed by similar processes, except that the RRAM cell stack 2701 has planar layers and lacks the barrier layer 125 (see FIG. 10). The bottom electrode via 701 may provide a barrier layer.

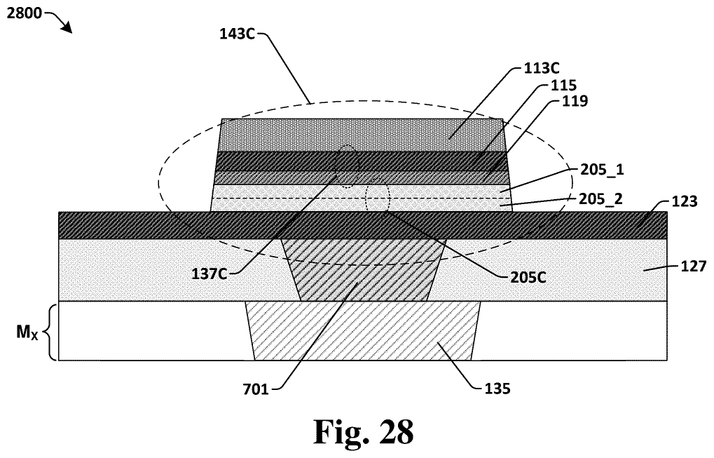

As illustrated by the cross-sectional view 2800 of FIG. 28, the hard mask 113C may be formed and the first etch process carried out to define the top electrode 137C. The etch process may stop on one of the resistive switching layers or may continue through the resistive switching layers to define the resistive switching structure 121C as depicted in FIG. 28.

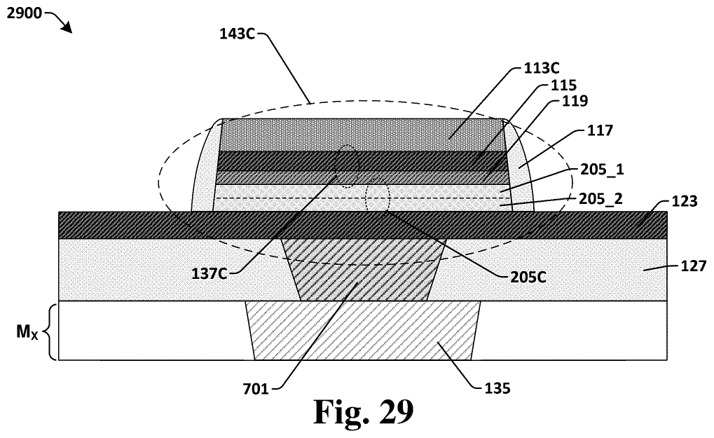

As illustrated by the cross-sectional view 2900 of FIG. 29, the sidewall spacer 117 may be formed around the sidewalls of the top electrode 137C and the resistive switching structure 121C. The process may be similar to the one described in connection with the cross-sectional view 2000 of FIG. 20.

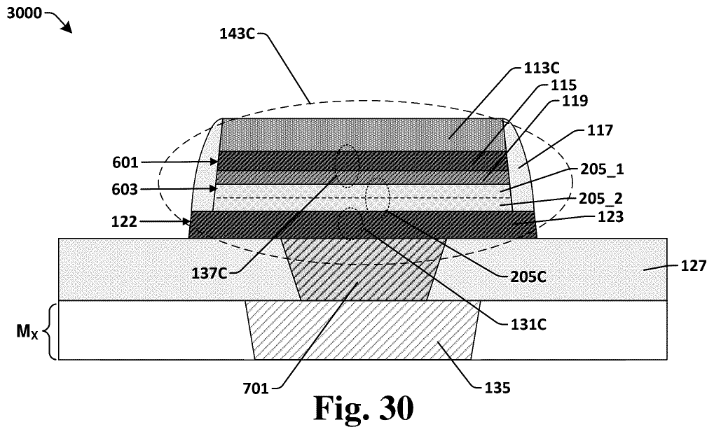

As illustrated by the cross-sectional view 3000 of FIG. 30, the second etch process may be employed to define the bottom electrode 131C and the RRAM cell 143C. In this embodiment, the second etch process may stop on the dielectric layer 127.

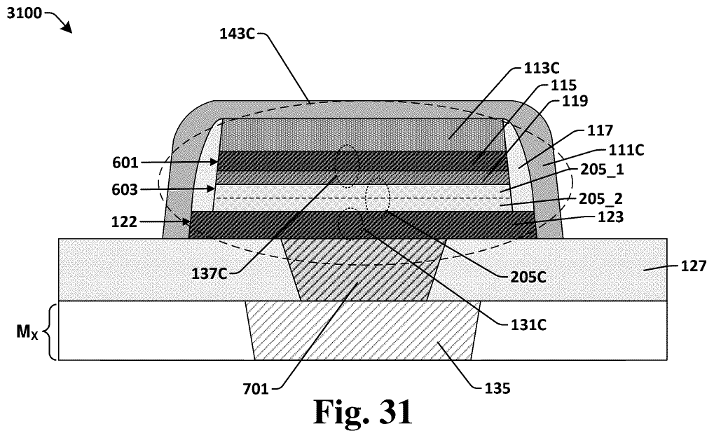

As illustrated by the cross-sectional view 3100 of FIG. 31, the non-oxide dielectric layer 111C may be formed over the RRAM cell 143C. The non-oxide dielectric layer 111C may be formed by deposition and etching, or by deposition alone. The non-oxide dielectric layer 111C may by left extending over the RRAM cell 143C as depicted in FIG. 31 or may be etched to the form of a spacer as depicted in the cross-sectional view 2300 of FIG. 23.

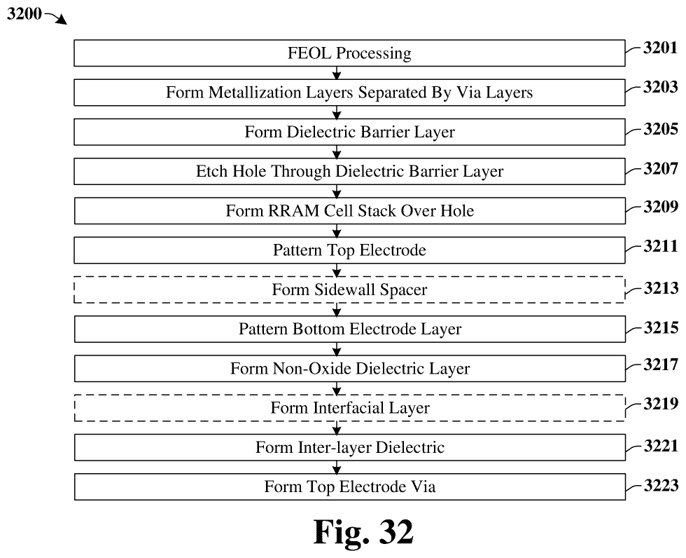

FIG. 32 provides a flow chart for a method 3200 of forming an RRAM cell according to some embodiments of the present disclosure. Although the method 3200 is illustrated and/or described as series of acts or events, it will be appreciated that these methods are not limited to the illustrated orderings or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

The method 3200 begins with act 3201, FEOL processing, and act 3203, forming a plurality of metallization layers interleaved with via layers. The cross-sectional view 800 of FIG. 8 provides an example. The examples of the present disclosure show RRAM cells being formed directly over metallization layers, and RRAM cells that are contained within a single via layer, but the RRAM cells may be disposed anywhere in a metal interconnect structure, or elsewhere within an integrated circuit device. The RRAM cells may be offset above metallization layers and connected thereto with vias.

Act 3205 is forming a dielectric barrier layer. Act 3207 is etching a hole through that layer. A conductive structure, such as a conductive trace, is exposed through the hole. The cross-sectional view 900 of FIG. 9 provides an example.

Act 3209 is forming an RRAM cell stack over the hole. The cross-sectional views 1000, 1800, and 2700 of FIGS. 10, 18, and 27 provide examples. In some embodiments, conformal deposition processes are employed, resulting in each of the layers having a central depression over the hole.

Act 3211 is patterning to define the top electrode from the RRAM cell stack. This has been referred to as the first etch process. The cross-sectional views 1100, 1900, 2400, and 2800 of FIGS. 11, 19, 24, and 28 provide examples. The first etch process may also define the resistance switching structure from the RRAM cell stack.

Act 3213 is an optional step of forming a sidewall spacer around the top electrode. The cross-sectional views 1200, 2000, and 2900 of FIGS. 12, 20, and 29 provide examples.

Act 3215 is patterning to define the bottom electrode from the RRAM cell stack. This has been referred to as the second etch process. The cross-sectional views 1300, 2100, 2400, and 3000 of FIGS. 13, 21, 24, and 30 provide examples. The second etch process defines the resistance switching structure from the RRAM cell stack if this was not accomplished by act 3211. If act 3213 was used to form a sidewall spacer, the bottom electrode is patterned in alignment with the sidewall spacer.

Act 3217 is forming a non-oxide dielectric layer. The non-oxide dielectric layer covers and protects a sidewall of the bottom electrode. In some embodiments, the non-oxide dielectric layer is etched into the form of a spacer. In some embodiments, the non-oxide dielectric layer extends over the RRAM cell. In some embodiments, the extent of the non-oxide dielectric layer is limited to the sides of the RRAM cell. The cross-sectional views 1400 and 1500 of FIGS. 14 and 15 provide one example, the cross-sectional views 2200 and 2300 of FIGS. 22 and 15 provide another example, the cross-sectional views 2500 of FIG. 25 provides a third example, and the cross-sectional views 3000 of FIG. 30 provides a fourth example.

Act 3219 is an optional step of forming an interfacial layer, and act 3221 depositing an inter-layer dielectric. The non-oxide dielectric layer protects the bottom electrode during these process steps. The cross-sectional view 1600 of FIG. 16 provides an example. In some embodiments, the interfacial layer binds the inter-layer dielectric to the non-oxide dielectric layer. In some embodiments, the interfacial layer is omitted, and the inter-layer dielectric layer directly contacts the non-oxide dielectric layer.

Act 3223 is forming a top electrode via. The top electrode via passes through the inter-layer dielectric to contact the top electrode. The cross-sectional view 1700 of FIG. 17 provides an example illustrating a first phase of this process.

Some aspects of the present disclosure relate to a semiconductor device that includes an RRAM cell in a metal interconnect structure disposed over a semiconductor substrate. The metal interconnect structure includes a plurality of metallization layers separated by via layers, each metallization layer comprising conductive traces surrounded by an inter-layer dielectric (ILD), and each via layer comprising conductive vias that interconnect the conductive traces and are surrounded by the inter-layer dielectric. The RRAM cell includes a bottom electrode, a top electrode, and a resistive switching structure located between the bottom electrode and the top electrode. A non-oxide dielectric layer surrounding the bottom electrode, wherein the non-oxide dielectric layer provides a physical barrier between the bottom electrode and the inter-layer dielectric.

In some embodiments, a sidewall spacer is disposed along outer sidewalls of the top electrode and positioned entirely above the bottom electrode. In some embodiments, the sidewall spacer is a non-oxide dielectric. In some embodiments, the non-oxide dielectric layer is disposed along outer sidewalls of the sidewall spacer. In some embodiments, the sidewall spacer the non-oxide dielectric layer abuts the top electrode in an area above the sidewall spacer.

In some embodiments, there is a hard mask over the RRAM cell and the non-oxide dielectric layer extends over the hard mask. In some embodiments, the sidewall spacer the hard mask is disposed between the non-oxide dielectric layer and a central depression in the top electrode. In some embodiments, the hard mask is confined to elevations below a peak elevation of an upper surface of the top electrode. In some embodiments, there is a silicon dioxide layer between the non-oxide dielectric layer and the ILD, and the ILD is a low-k dielectric. In some embodiments, the non-oxide dielectric layer comprises silicon carbide (SiC), silicon nitride (SiN), or silicon carbonitride (SICN).

In some embodiments, the bottom electrode includes a central depression and a slanted sidewall, and the bottom electrode slopes upward continuously from the central depression to the slanted sidewall. In some embodiments, the non-oxide dielectric layer abuts the slanted sidewall.

In some embodiments, the bottom electrode comprises a first layer over a second layer, the second layer is at least as thick as the first layer, and the second layer is in contact with one of the conductive traces. In some embodiments, the conductive trace comprises copper. In some embodiments, the second layer is an oxide, a nitride, or an oxynitride of a metal or metal alloy.

In some embodiments, the resistive switching structure comprises one or more metal oxides, and the RRAM cell is of a type in which a conductive filament is formed by oxygen vacancies in the resistive switching structure. In some embodiments, the resistive switching structure comprises a first layer proximate the bottom electrode and a second layer proximate the top electrode. A majority of the first layer is oxides of a first metal, a majority of the second layer is oxides of a second metal, and the second metal has a higher oxygen affinity than the first metal.

In some embodiments, the bottom electrode layer is disposed over a dielectric barrier layer, has a central portion disposed over a hole though the dielectric barrier layer, has a peripheral portion disposed over a slanted sidewall of the dielectric barrier layer surrounding the hole, and has a tapered surface connecting a surface of the peripheral portion to a surface of the central portion. In some embodiments, the dielectric barrier layer is non-oxide dielectric.

Some aspects of the present disclosure relate to a semiconductor device that includes an RRAM cell in a metal interconnect structure disposed over a semiconductor substrate. The metal interconnect structure includes a plurality of metallization layers separated by via layers, each metallization layer comprising conductive traces surrounded by an inter-layer dielectric (ILD), and each via layer comprising conductive vias that interconnect the conductive traces and are surrounded by the inter-layer dielectric. The RRAM cell includes a bottom electrode, a top electrode, and a resistive switching structure located between the bottom electrode and the top electrode. A first spacer is disposed on an upper surface of the resistive switching structure and along outer sidewalls of the top electrode. A second spacer surrounding the bottom electrode, wherein the second spacer provides a physical barrier between the bottom electrode and the inter-layer dielectric and is of a type that may be formed in an oxygen-free deposition process. In some embodiments, there is an interfacial layer between the second spacer and the inter-layer dielectric. The interfacial layer may be an oxide layer

Some aspects of the present disclosure relate to a method of manufacturing an integrated circuit device. The method includes forming a metallization layer over a surface of the semiconductor substrate, depositing a dielectric layer over the metallization layer, forming a hole through the dielectric layer, wherein a conductive trace in the metallization layer is exposed through the hole, depositing a bottom electrode layer, a resistive switching layer, and a top electrode layer over the dielectric layer and the hole so that each of the bottom electrode layer, the resistive switching layer, and the top electrode layer have central depressions over the hole, forming a hard mask over the top electrode layer, performing a first etch process to etch through the top electrode layer and define a top electrode, forming a sidewall spacer around the top electrode, using a second etch process to etch through the bottom electrode layer to define a bottom electrode and expose a bottom electrode sidewall. Either the first etch process or the second etch process etches through the resistive switching layer to define a resistive switching structure, and the bottom electrode, the top electrode, and the resistive switching structure together provide an RRAM cell. The method further includes depositing a non-oxide dielectric layer over the bottom electrode sidewall using a substantially oxygen-free deposition process, and depositing an inter-layer dielectric (ILD), wherein the non-oxide dielectric layer protects the bottom electrode from oxidation during the deposition of the ILD.

In some embodiments, the second etch process provides the bottom electrode with a sloping sidewall that tapers at an angle relative to the surface of the semiconductor substrate. In some embodiments, the first etch process provides the top electrode with a sloping sidewall that tapers at an angle relative to the surface of the semiconductor substrate. In some embodiments, a bottom of the sidewall spacer slopes upward from the central depression. In some embodiments, the second etch process etches through a portion of the hard mask whereby a portion of the top electrode is exposed, and the oxide free dielectric covers the exposed portion. In some embodiments, the hole has a tapering sidewall, and the bottom electrode sidewall extends from the tapering sidewall. In some embodiments, the method further includes depositing a silicon dioxide layer that adheres the oxide free dielectric by the silicon dioxide layer.

In some embodiments, depositing the resistive switching layer comprises depositing a first layer that comprises an oxide of a first metal followed by deposition of a second layer that comprises an oxide of a second metal, wherein the first metal has a lower standard Gibbs free energy of oxygen vacancy formation for its maximum oxide than does the second metal. In some embodiments, depositing the first layer comprises depositing the oxide of the first metal and depositing an oxide of a third metal, wherein the oxide of the first metal and the oxide of the third metal are deposited in distinct cycles of atomic layer deposition, and the first metal has a lower standard Gibbs free energy of oxygen vacancy formation for its maximum oxide than does the third metal.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit device, comprising:
a metal interconnect structure disposed over a semiconductor substrate, wherein the metal interconnect structure includes a plurality of metallization layers separated by via layers, each metallization layer comprising conductive traces surrounded by an inter-layer dielectric (ILD), and each via layer comprising conductive vias that interconnect the conductive traces and are surrounded by the inter-layer dielectric;
an RRAM (Resistive Random Access Memory) cell comprising a bottom electrode, a top electrode, and a resistive switching structure located between the bottom electrode and the top electrode, wherein the RRAM cell is integrated within the metal interconnect structure; and
a non-oxide dielectric layer surrounding the bottom electrode, wherein the non-oxide dielectric layer provides a physical barrier between the bottom electrode and the inter-layer dielectric.

2. The integrated circuit device of claim 1, further comprising a sidewall spacer disposed along outer sidewalls of the top electrode and positioned entirely above the bottom electrode.

3. The integrated circuit device of claim 2, wherein the sidewall spacer is a non-oxide dielectric.

4. The integrated circuit device of claim 2, wherein the non-oxide dielectric layer is disposed along outer sidewalls of the sidewall spacer.

5. The integrated circuit device of claim 4, wherein the non-oxide dielectric layer abuts the top electrode in an area above the sidewall spacer.

6. The integrated circuit device of claim 1, further comprising a silicon dioxide layer between the non-oxide dielectric layer and the ILD, wherein the ILD is a low-k dielectric.

7. The integrated circuit device of claim 6, wherein the non-oxide dielectric layer comprises silicon carbide (SiC), silicon nitride (SiN), or silicon carbonitride (SICN).

8. The integrated circuit device of claim 1, wherein:
the bottom electrode includes a central depression and a slanted sidewall; and
the bottom electrode slopes upward continuously from the central depression to the slanted sidewall.

9. The integrated circuit device of claim 8, wherein:
the bottom electrode comprises a first layer over a second layer;
the second layer is at least as thick as the first layer;
the second layer is in contact with one of the conductive traces; and
the conductive trace comprises copper.

10. The integrated circuit device of claim 9, wherein the second layer is an oxide, a nitride, or an oxynitride of a metal or metal alloy.

11. The integrated circuit device of claim 1, the resistive switching structure comprises a first layer proximate the bottom electrode and a second layer proximate the top electrode, wherein a majority of the first layer is oxides of a first metal, a majority of the second layer is oxides of a second metal, and the second metal has a higher oxygen affinity than the first metal.

12. An integrated circuit device, comprising:
a metal interconnect structure disposed over a semiconductor substrate, wherein the metal interconnect structure includes a plurality of metallization layers separated by via layers, each metallization layer comprising conductive traces surrounded by an inter-layer dielectric (ILD), and each via layer comprising conductive vias that interconnect the conductive traces and are surrounded by the inter-layer dielectric;
an RRAM (Resistive Random Access Memory) cell comprising a bottom electrode, a top electrode, and a resistive switching structure located between the bottom electrode and the top electrode, wherein the RRAM cell is integrated within the metal interconnect structure, and an upper surface of the top electrode includes a tapered recess;
a first spacer disposed on an upper surface of the resistive switching structure and along outer sidewalls of the top electrode; and
a second dielectric layer surrounding the bottom electrode, wherein the second dielectric layer provides a physical barrier between the bottom electrode and the inter-layer dielectric and is of a type that may be formed in an oxygen-free deposition process.

13. The integrated circuit device of claim 12, further comprising an interfacial layer providing between the second dielectric layer and the inter-layer dielectric, wherein the interfacial layer is an oxide.

14. A method of manufacturing an integrated circuit device, the method comprising:
forming a metallization layer over a surface of the semiconductor substrate, wherein the metallization layer comprises a conductive trace;
depositing a dielectric layer over the metallization layer;
forming a hole through the dielectric layer, wherein the conductive trace is exposed through the hole;
depositing a bottom electrode layer, a resistive switching structure, and a top electrode layer over the dielectric layer and the hole, wherein each of the bottom electrode layer, the resistive switching structure, and the top electrode layer have central depressions over the hole;
forming a hard mask over the top electrode layer;
performing a first etch process to etch through the top electrode layer and define a top electrode;
forming a sidewall spacer around the top electrode;
using a second etch process to etch through the bottom electrode layer to define a bottom electrode and expose a bottom electrode sidewall, wherein either the first etch process or the second etch process etches through the resistive switching structure to define a resistive switching structure, and the bottom electrode, the top electrode, and the resistive switching structure together provide a resistive random-access memory (RRAM) cell;
depositing a non-oxide dielectric layer over the bottom electrode sidewall using a substantially oxygen-free deposition process; and
depositing an inter-layer dielectric (ILD), wherein the non-oxide dielectric layer protects the bottom electrode from oxidation during the deposition of the ILD.

15. The method of claim 14, wherein the second etch process provides the bottom electrode with a sloping sidewall that tapers at an angle relative to the surface of the semiconductor substrate.

16. The method of claim 14, wherein the first etch process provides the top electrode with a sloping sidewall that tapers at an angle relative to the surface of the semiconductor substrate.

17. The method of claim 16, wherein a bottom of the sidewall spacer slopes upward from the central depression.

18. The method of claim 14, wherein the second etch process etches through a portion of the hard mask whereby a portion of the top electrode is exposed, and the oxide free dielectric covers the exposed portion.

19. The method of claim 14, further comprising depositing a silicon dioxide layer, wherein the ILD is adhered to the oxide free dielectric by the silicon dioxide layer.

20. The method of claim 14, wherein depositing the resistive switching structure comprises depositing a first layer that comprises an oxide of a first metal followed by deposition of a second layer that comprises an oxide of a second metal, wherein the first metal has a lower standard Gibbs free energy of oxygen vacancy formation for its maximum oxide than does the second metal.
